(19) United States
(12) Patent Application Publication
(10) Pub. No.: US 2016/0005902 A1
(43) Pub. Date: Jan. 7, 2016

(54) Direct Thermal Path Heat Sinking Using Fins Formed From Energy Conversion Device Components, Including Subcomponents of Vertical Multijunction Photovoltaic Receivers Used For High Intensity Beaming and Wireless Power Transmission

(71) Applicants: Chiun-Yen Tung, Kaohsiung City (TW); Mei-huan Yang, Kaohsiung City (TW); Terry Zahuranec, North Olmsted, OH (US); Remigio Perales, Oberlin, OH (US); Te-Chih Huang, Kaohsiung City (TW); Jheng-Syuan Shih, Kaohsiung City (TW); Cheng-Liang Wu, Kaohsiung City (TW); Chin-Wei Hsu, Zhongli City (TW)

(72) Inventors: Chiun-Yen Tung, Kaohsiung City (TW); Mei-huan Yang, Kaohsiung City (TW); Terry Zahuranec, North Olmsted, OH (US); Remigio Perales, Oberlin, OH (US); Te-Chih Huang, Kaohsiung City (TW); Jheng-Syuan Shih, Kaohsiung City (TW); Cheng-Liang Wu, Kaohsiung City (TW); Chin-Wei Hsu, Zhongli City (TW)

(73) Assignee: MH Solar Co., LTD., Kaohsiung City (TW)

(21) Appl. No.: 14/530,619

(22) Filed: Oct. 31, 2014

Related U.S. Application Data
(63) Continuation of application No. 14/324,040, filed on Jul. 3, 2014.

(51) Int. Cl. H01L 31/052; H01L 31/0725

(52) U.S. Cl. CPC H01L 31/052; H01L 31/0725

(57) ABSTRACT

New high energy operating regimes for high intensity energy transfer for beam receiving, signal acquisition, and beam or signal generation for power beaming and wireless power transmission are made possible by new direct thermal pathways for heat sinking, where an energy conversion device comprises a plurality of fins [1] originating from inside the energy conversion device; [2] formed from an energy conversion device component; and where those fins [3] individually support traffic in energy carriers essential to the function of the energy conversion device. This allows high energy thermal interfacing and high intensity energy conversion, such as for receiving and transducing extremely high intensity light shined onto a small surface semiconductor device such as a vertical multijunction photovoltaic receiver. This allows high intensity energy transfer for beam receiving, signal acquisition, and beam or signal generation for high intensity power beaming and wireless power transmission.

This is a continuation-in-part application directed to subject matter described and claimed in parent application Ser. No. 14/324,040 as originally filed 3 Jul. 2014. The entire disclosure of this prior original (parent) application is hereby incorporated herein by reference in its entirety.

### TECHNICAL FIELD

This invention relates to novel structures and methods for direct thermal path heat sinking for, and thermal communication with energy conversion devices such as vertical multijunction photovoltaic cell arrays, and solid state lasers, and other high power semiconductor devices.

The invention can be used to supplement thermal and electrical/optical interfacing for three-dimensional optoelectronic devices, such as semiconductor device billets, to allow high intensity operation, such as for receiving and transducing extremely high intensity light shined onto a small surface semiconductor optoelectronic device such as a photovoltaic receiver or cell, transducer, waveguide or splitter. The emphasis in this disclosure shall be on use of the instant teachings for energy transfer, beam receiving, signal acquisition, and beam or signal generation in, out and about a three-dimensional optoelectronic device, three-dimensional photovoltaic receiver billet, or other transducing material body. Preferred embodiments include heat sinking for edge-illuminated vertical multijunction photovoltaic receivers operating under hundreds or thousands of suns intensity.

### BACKGROUND OF THE INVENTION

Cooling of high power semiconductor and other energy conversion devices is essential to their longevity and safe operation, and to the development of new applications such as vertical multijunction photovoltaic cell arrays and the use of power beaming where laser or other light is used to deliver electric power to drones, cell phones, and other devices. Heat sinks and other passive cooling devices, as well as active cooling devices such as Peltier coolers, have played an essential role in the continued success of new technologies which depend critically upon dissipation of heat from critical components and devices. Heat flows have been studied in great depth, including study of radiative, convection, and conduction processes in and around device perimeters. The need for low thermal resistance thermal pathways away from energy conversion devices has never been greater. Thermal failure is a major design consideration and sometimes has the effect of ruling out the viability of promising new applications that would otherwise meet success.

Heat sinks are extremely common in electronic systems and in certain energy conversion technologies, including even waveform inverters and the like. The use of cooling fins has become a well developed art. Prior art descriptions of heat sinking technologies include U.S. Pat. No. 7,109,520 to Yu et al; U.S. Pat. No. 6,543,521 to Sato et al; U.S. Pat. No. 8,537,554 to Hockaday; and US Patent Publication 2013/0320356 to Torabi et al. Cooling fins normally originate from a thermal plane that is in direct or indirect contact with an energy conversion or other device, across a cover or backing plate, or by mere thermal contact with the device. Such heat sinks are exterior to the device and are not involved in any flow of energy carriers such as electric charge carriers or photons in the device.

The development of high power lasers, especially semiconductor lasers and laser diodes has introduced even more need for high level dissipation of heat, because these systems often generate substantial energy losses, causing high localized and pernicious component heating.

Also, generally, the field of energy conversion is undergoing large changes as direct energy conversion processes such as photovoltaic conversion are becoming less costly and are meeting higher engineering benchmarks that allow for large scale implementation and for new applications in disparate fields such as robotics and aerospace industries. Engineers have long contemplated using high intensity energy conversion, such as high intensity photovoltaic conversion to make possible remote signal and/or power transmission using lasers or flux beams in conjunction with concentrated solar power (CSP), wireless power transmission (WPT), and high intensity laser power beaming (HILPB), such as for energizing or recharging power supplies on unmanned aerial vehicles (UAVs) or drones.

Among the many references discussing these applications are US Patent Publication 2008/0245930 to Nayfeh et. al., “High Intensity Laser Power Beaming for Space and Terrestrial Applications,”—and also—Raible, Daniel E.; Fast, Brian R.; Dinca, Dragos; Nayfeh, Taysir H. and Jalics, Andrew K., Comparison of Square and Radial Geometries for High Intensity Laser Power Beaming Receivers, NASA/TM—2012-217255, ISBN 978-1-4244-9686-0; both hereby incorporated by reference herein in their entirety.

The success of these new initiatives very much hinges upon device limitations—typically semiconductor device limitations—and engineering constraints. For illustrative purposes, and also to inform regarding preferred embodiments, the instant teachings can be applied to photovoltaic receivers and cells.

Photovoltaic receivers, and photovoltaic energy conversion generally, typically make use of the photovoltaic effect. Solar cells use this effect inside what are usually traditional solid-state semiconductors, formed by single or multiple lattices of semiconductor crystals with two alternating type of dopants—those doped with n-type impurities to form n-type semiconductors, which provide a free population of conduction band electrons, and those doped with p-type impurities to form p-type semiconductors, which add what are called electron holes. Electrons flow across the lattice boundaries to equalize the Fermi levels of the two differently doped materials. This results in what is called charge depletion at the interface, called the p-n junction, where charge carrier populations are depleted or accumulated on each side.

Sunlight, for example, can cause photo excitation of electrons on the p-type side of the semiconductor lattice, which can cause electrons from a lower-energy valence band to pass into a higher-energy conduction band. These electrons, after subtracting various energy and charge carrier losses, can do work across an electrical load as they flow out of the p-type side of the lattice to the n-type side. The result is a known and mature direct energy conversion process which offers relatively high conversion efficiencies, especially if light of selected wavelengths is selected for absorption.

Recently, energy efficiencies have gone up via a newer type of lattice construction using multiple junctions which are custom fabricated using different semiconductor materials and dopants to operate efficiently for selected wavelengths. Development of these and other enhanced photovoltaic technologies, such as vertical multijunction (VMJ) photovoltaic cells, offer promise for concentrated solar photovoltaics. In a photovoltaic device, each semiconductor or other material can create a p-n junction or interface that produces charge carrier current in response to a select distribution of wavelengths of light. Such multijunction photovoltaic cells provide optimal light-to-electricity conversion at multiple or select wavelengths of light, which can increase overall energy conversion efficiency. Traditional single-junction cells have a maximum theoretical efficiency of 34%. Theoretically, multijunction photovoltaics have a maximum theoretical efficiency in excess of 50% under highly concentrated sunlight. In addition, high voltage silicon vertical multijunction photovoltaic solar cells made using recently developed fabrication techniques are ideally suited for beam-split concentrated light applications, as they are capable of conversion of light intensities of tens or hundreds or thousands of suns intensity AM1.5.

Structurally, VMJ cells are an integrally bonded series-connected array of miniature silicon vertical unit junctions. They offer design simplicity, low cost, and an innovative edge-wise entry for light that allows for easy and controlled absorption and conversion at the high energy levels produced by hybrid concentrated solar power. Their higher per-unit cost relative to single junction photovoltaics can be more than justified by their ability to handle and convert concentrated solar power and the high voltage they produce is more easily handled electrically by power conditioning systems that prepare the photovoltaic power for use in an application, such as for remote power transfer.

Vertical multijunction photovoltaic receivers can be used to great advantage in hybrid thermal/photovoltaic systems, and for laser-assisted or beam-assisted remote power transfer. They are easily fabricated and assembled into units that produce high voltage, low current devices that offer myriad advantages, as discussed in IEEE and other proceedings, such as—B. L. Sater, N. D. Sater, “High voltage silicon VMJ solar cells for up to 1000 suns intensities,” Photovoltaic Specialists Conference, 2002. Conference Record of the Twenty-Ninth IEEE, Publication Date 19-24 May 2002, pgs. 1019-1022 ISSN 1060-8371, ISBN 0-7803-7471-1—hereby incorporated by reference herein in its entirety.

As with all semiconductor devices, thermal considerations can be critical. With applications contemplated that result in energy transfer intensities equivalent to more than 1000 suns, exposure levels can approach and surpass one million watts/meter̂2 on the surface of a semiconductor device. This high intensity can cause meltdown or drops in performance. In many particular photovoltaic applications at an illustrative base temperature of 100 C during operation, each 10 C increase in temperature can results in an approximately three percent reduction in energy conversion performance, and high temperatures reduce operating life. So while it is true that high voltage photovoltaic receivers such as vertical multijunction photovoltaic receivers are now the subject of intense research and development efforts worldwide, their potential in meeting long known engineering requirements is promising but still threatened. There are problems in certain cases with diffusion processes degrading device dynamics, and the thermal loads for large energy transfer or flux-receiving optoelectronic devices, such as three-dimensional optoelectronic device billets, can cause damage from high temperature operation. Specifically, for output devices, such as the three-dimensional optoelectronic output device billets illustratively included in this disclosure that would include high power semiconductor lasers, the possibility of catastrophic optical damage (COD), or catastrophic optical mirror damage (COMD), represents a failure mode of high-power semiconductor lasers that can afflict devices when the operative semiconductor junction is overloaded thermally, such as by exceeding its power density and absorbing excessive produced light. This can produce ill effects such as melting, recrystallization, and defect production in and around the semiconductor material at the facets of the laser. It represents the primary failure mode for certain aluminum GaAs lasers, and the resultant newly formed existence of surface state energy levels in otherwise forbidden band gap energy levels can cause damage in other systems as well. Positive feedback mechanisms of thermal runaway can result in total device failure.

Prior art attempts at thermal management fall short to insure problem-free operation of semiconductor devices. Prior art devices often attempt to solve this problem using thermally conductive pathways such as found in U.S. Pat. No. 7,985,919 to Roscheisen et al. where known heat sink materials are simply laid out like a bed underneath the semiconductor device in question, sometimes supplemented by external features like fins. A whole array of materials is often enlisted in this effort to conduct away heat. But even with known heat sink materials such as stainless steel, aluminum, copper, aluminum, and other known materials exhibiting excellent heat conduction characteristics, they are no match for high intensity beam handling applications where a 2×2 cm device can be receiving in excess of 400 watts luminous power, with thermal transfer on the order of about 1.000 W/cm° C. or greater being limited by spatial access and thermal diffusive efficiency.

One objective of the instant invention is to provide a novel arrangement for thermal and optoelectronic interfacing and mounting for all manner of three-dimensional optoelectronic device billets. Another objective is to provide for successful, sustained operation of three-dimensional optoelectronic device billets, three-dimensional photovoltaic receiver billets, and three-dimensional optoelectronic output device billets under high intensity operation that would otherwise damage them or reduce their effectiveness, overall efficiency, and service lifetimes.

Furthermore, with the performance of so many devices dependent on their ability to dissipate heat, the role of valence electrons and phonons can also make for a vicious cycle or critical situation where increased operating temperatures result in lower effective thermal take-away from active components,because the value of thermal conductivity in W/(mK) drops, and the effects on device longevity and reliability can be disastrous. When a loss of thermal conductivity causes a rise in device operating temperature, the rise in temperature can lead to further increases in energy carrier flow or current flow, and a subsequent further rise in temperature, which worsens until the device dynamics spiral out of control and the device is destroyed.

It is an objective of the instant invention to provide a way to increase yet further the heat dissipation tools available to the design of all manner of energy conversion devices by making available a direct thermal pathway that provides for successful deployment of new technologies in higher energy transfer operating regimes than have ever before been possible.

### SUMMARY OF THE INVENTION

The invention provides for heat dissipation from energy conversion devices where an active energy conversion device component forms a bona fide fin, and where no thermal interface required to bond thermally to a heat sink. The thermal path itself is altered so that instead of having cooling fins or the equivalent thermally originating from a heat sink plane or heat sink component, the fins originate from inside the energy conversion device.

The invention includes:

An energy conversion device in thermal communication with a plurality of fins at least partially forming a heat sink, each of the fins
[1] originating from inside the energy conversion device;
[2] formed from an energy conversion device component; and where those fins
[3] individually support traffic in energy carriers essential to the function of the energy conversion device.

The energy conversion device can be a vertical multijunction (VMJ) cell array.

The invention also comprises a method for thermal communication with energy conversion device components in an energy conversion device, with the method comprising:
[1] drawing heat out through a plurality of the energy conversion device components that individually support traffic in energy carriers essential to the function of the energy conversion device, where the plurality of energy conversion device components are finned and protrude sufficiently beyond a device boundary to allow significant thermal transfer; and
[2] effecting the significant thermal transfer from the finned energy conversion device components via exposure to at least one of ambient air, a convection medium, and contact conduction with a thermal bed.

The invention can also comprise a heat sink array for an energy conversion device, the heat sink array comprising a plurality of fins, each of the fins originating from inside the energy conversion device, formed from an energy conversion device component; and individually supporting traffic in energy carriers essential to the function of the energy conversion device. The heat sink array thus formed can be formed and positioned to be in direct thermal communication with a thermal bed, such as a bed of indium metal, via contact conduction.

### BRIEF DESCRIPTION OF THE DRAWINGS

FIG. 1 shows an oblique surface schematic view of a prior art edge-illuminated vertical multijunction photovoltaic receiver array, illustratively shown with schematic thermal flow;

FIG. 2 shows an oblique surface schematic view of a individual cell from a prior art vertical multijunction photovoltaic receiver array;

FIG. 3 shows a cross-sectional schematic diagram of a prior art edge-illuminated vertical multijunction photovoltaic receiver array, showing mounting and schematic thermal flow;

FIG. 4 shows a cross-sectional schematic diagram of a general energy conversion device similar to the illustrative vertical multijunction photovoltaic receiver of FIG. 3, with schematic illustrative thermal flow;

FIG. 5 shows a close-up view of the cross-sectional schematic diagram of the general energy conversion device of FIG. 4, showing thermal flow and energy carriers essential to function of the device, with a heat sink formed separately and in thermal communication across an interface;

FIG. 6 shows a top partial surface view, looking down, of a relatively flat general energy conversion device like that shown in FIGS. 4 and 5, but embodying the instant invention and employing cooling fins formed from energy conversion device components;

FIG. 7 shows a simplified schematic thermal flow chart for a prior art general energy conversion device using a conventional prior art heat sink;

FIG. 8 shows a simplified schematic thermal flow chart for a general energy conversion device cooled using the instant invention;

FIGS. 9-11 show oblique surface views of three illustrative prior art three-dimensional energy conversion or optoelectronic device billets that can be improved by practicing the invention, with incident beams impinging upon or emerging from billet entry sides;

FIG. 12 shows an oblique surface view of an energy conversion device illustratively shown as a relatively flat vertical multijunction photovoltaic cell array with heat sinking provided according to the instant invention;

FIG. 13 shows a close-up of a portion of the oblique surface view of the energy conversion device of FIG. 12, showing a thermal path for heat dissipation;

FIGS. 14 and 15 show oblique surface views of another embodiment of an energy conversion device illustratively shown as a relatively flat vertical multijunction photovoltaic cell array with heat sinking provided according to the instant invention, featuring a thermal bed, and with the device of FIG. 15 comprising a retroreflector;

FIG. 16 shows an underside oblique surface view of the energy conversion device of FIG. 15, with the retroreflector tucked under the energy conversion device;

FIG. 17 shows an oblique surface view of an energy conversion device similar to that illustratively shown as a relatively flat vertical multijunction photovoltaic cell array with heat sinking provided according to the instant invention of FIG. 12, with energy conversion device components forming a heat sink array under the device;

FIG. 18 shows simplified schematic chart for a method for thermal communication according to the invention;

FIG. 19 shows an oblique surface view of an energy conversion device according to the invention with a heat sink array and heat sink holding structures;

FIG. 20 shows an oblique partial cut-out surface view of an energy conversion device illustratively shown as a three-dimensional optoelectronic device billet according to the invention similar to that shown in FIG. 19, and showing illustrative internal and external cooling systems inside the heat sink holding structure;

FIG. 21 shows a simple representative cartesian plot of the cell operating temperature of a energy conversion device vertical multijunction cell array as a function of incident intensity of light for photovoltaic conversion, for both a prior art device and a device using the instant invention;

FIGS. 22 and 23 show differing oblique surface views of a relatively flat energy conversion device with heat sinking according to the invention, using twin thermal beds.

### DEFINITIONS

The following definitions shall be used throughout:
Ambient environment—shall denote any relevant space around an energy conversion device to which thermal communication is directed according to the invention, and can include air, water, oil, coolant, or other material medium(s), as well as active thermoelectric coolers such as Seebeck or Peltier Effect coolers. Such an ambient environment can exist in open air, or in a tank or enclosure of any kind, including an enclosure filled with a coolant medium such as a fluid or gas.
Beam—shall comprise any energy transfer or beam of electromagnetic radiation such as light, or electromagnetic flux, such as electrical and/or magnetic flux or other electromagnetic excitation or thermal excitation from any source used functionally to practice the instant invention. A beam can be so oriented to energize at least partially a billet, such as a three-dimensional optoelectronic device billet, a three-dimensional photovoltaic receiver billet, or a three-dimensional optoelectronic output device billet as taught herein. A beam can include radiation not confined to a collimated, coherent or pencil-like beam shape, or not confined to impingement onto the billets illustratively shown, and therefore can include flux swaths or light spots larger than the receiver in the illustrative embodiments that are shown and described here for clarity.
Billet shall be defined broadly and comprises an energy conversion device as herein defined. A billet can include any and all associated reflective, refractive, optical, electrical, or surface components, such as lenses or other desired device components without departing from the this definition.
Communicating—shall by context include communication for signal transmission as well as power transmission, delivery of a thermal fluid or coolant, thermal or heat flow, electrical currents, electromotive force, optical flux or any electromagnetic flux, including varying magnetic fields.
Energy carriers—shall include photons, electric charge (positive or negative, including ions) or electrically charged particles or bodies; motion, vibration or oscillations of any material substance, including molecules, electrons, atoms and phonons. As defined here, energy carriers shall also include the electric field inside a resonator and what are commonly referred to as electrons and holes.
Energy conversion device—shall be any electrical, electronic, optoelectronic, optical, glass, crystalline, quasi-crystalline or ceramic device or material body; or any transducer, sensor, memory device, photovoltaic cell, photovoltaic array, or other component-based device that operates as a functional device that receives, transforms, re-transmits, re-directs, emits, modulates, or transmits energy or energy carriers as defined here. This includes transistors, high power transistors, parallel transistors for high power applications that are often associated with integrated circuits and integrated circuit packages, such as CPUs and applied systems like ECUs, optoelectronic devices, photovoltaic cells, photovoltaic arrays, vertical multijunction cells and arrays, and lasers, including semiconductor lasers and laser diodes. In this regard, a stack of devices such as the wafers or laminations in a vertical multijunction (VMJ) cell are considered as part of one device, throughout this specifications and in the appended claims, even though individual subelements can be responsive as stand-alone devices. Included in this definition are various classes of amplifiers, especially classes A, B and AB, which offer high fidelity, and low distortion, but with increased power consumption and lower efficiency, which translates to a requirement to dissipate a high thermal load. A billet comprising an energy conversion device can include any and all associated reflective, refractive, optical, electrical, surface components, such as lenses or other desired device components, without departing from the invention.
Energy conversion device component—shall denote any substituent element that forms an active essential functional portion of an energy conversion device, or participates in an essential way in the traffic of energy carriers essential to the function of the energy conversion device. In power transistors, this can include the well known emitter/collector/base of a bipolar junction transistor; or the source/drain/gate or base of a field effect transistor, such as a MOSFET. It can include substituent ganged (e.g., series connected) wafers or laminations in a vertical multijunction photovoltaic cell; the gain medium, optical resonator of a solid state laser; or the p-type, n-type or quantum well body or material in a solid state laser.
Fin or heat transfer fin—shall refer to any material body or structure which acts as a thermal conductor or communicator that permits use according to the invention, whether or not it protrudes explicity or exteriorly from the body or a portion of the body of an energy conversion device. Fins as shown illustratively here are planar for clarity, but generally a fin can depart from a planar protrusion or a single protrusion, such as by employing needle shapes, spikes, undulating contours, or sub-fins. A fin does not have to be in thermal communication with a larger component, but rather itself can be of superior extent relative to the energy conversion device. A fin according to the invention can comprise other elements or structures, such as structures to enhance thermal transfer; passages for coolant or thermal transfer fluid; or active sub-devices such as piezoelectric coolers (not shown).
Flux shall refer to electromagnetic radiation, including all forms of light of all frequencies—energy flux in the general sense of the word—flux that allows transmission of power or a signal—and can include radiative flux, heat flux, particle flux, electromagnetic or any power flux, such as a Poynting flux.
Function of an energy conversion device—as in the appended claims, “essential to the function of said energy conversion device”—shall refer to desired or actual device operational functionality such as amplification, production of light, photovoltaic conversion of light, etc., and not to any thermal dissipation that is needed to achieve device longevity or to achieve device intended operation. This applies in spite of any doping of the material of a heat sink to enhance thermal conductivity, or be fabricated for compatibility with surrounding materials.
Heat sink surface—shall denote any surface or separable surface, or surface existing in a gel, liquid, or fluid format, that is so formed, shaped, positioned, oriented and maintained to effect thermal transfer of energy to or from a billet according to the invention.
Opposing surface shall, in the specification and appended claims and associated description, denote a surface that is spatial separated from and is either parallel or non-parallel with respect to another such surface, and can support thermal communication with a heat sink surface and an optoelectronic feed such as an anode or cathode.
Optoelectronic device shall include any billet as defined in this specification, and thus shall include passive devices such as crystals, such as a ruby crystal.
Optoelectronic feed shall denote any or both of electrical contacts or the equivalent; and optical waveguides or feedthroughs that are so formed to allow receiving, acquisition, or output from a billet.
Photovoltaic receiver—shall denote any conversion device using the Photovoltaic Effect, Photoelectric Effect, or other phenomena to convert incident light, such as solar light, laser light, or infrared light, to an electromotive force employed to drive electric charge carriers, negative and/or positive, and can in preferred embodiments, include vertical multijunction photovoltaic cells or heterostructures designed to produce high conversion efficiency.
Plane/planar—shall include surfaces or components or material bodies that are merely substantially planar, but may possess curved surfaces, small surface features, holes, spikes and other topographically anomalous or secondary features.
Receiver Waveguide shall denote any set of planar surfaces, curved surfaces, or any other surfaces so formed to operate, upon impingement of electromagnetic radiation or flux or any beam, to effect channeling, homogenization, concentration or intensifying onto, about, or into a billet or receiver according to the invention, and shall include any and all reflective, refractive, optical, or electrical components, or surface lenses or similar components, or other device components that accomplish same.
Signal—shall include, throughout the specification and appended claims, any and all signals for any purpose, using any carrier frequency, communication protocol, digital protocol or medium, including when a three-dimensional optoelectronic output device billet produces a beam that is intentionally modulated according to a communications protocol to convey information.
Thermal bed—shall denote any material body including a solid, liquid or a gas of any form or phase, which is so placed and formed as to communicate thermally with a fin or heat transfer fin according to the invention.
Thermal path—shall denote the essential direction of any prevalent temperature gradient formed as a result of heat production from essential operation of an energy conversion device as defined herein.
Three dimensional—shall characterize any optoelectronic component used according to the instant invention where first and second opposing billet surfaces of that optoelectronic component do not include a surface used primarily for non-thermal optoelectronic input, output, or communication.
Vertical Multijunction Photovoltaic Cell/Receiver—shall in this disclosure and in the appended claims denote any Multijunction Photovoltaic Cell or device so constructed, and formed, including material formulation, to comprise at least two substantially planar p-n junctions or interfaces or the charge carrier functional equivalent, and is further constructed, shaped and finished to allow disposition for light entry substantially parallel to, or at least at an acute angle with respect to at least one set of those planar junctions. This is in contrast to known single junctions photovoltaic cells or receivers.

### DETAILED DESCRIPTION

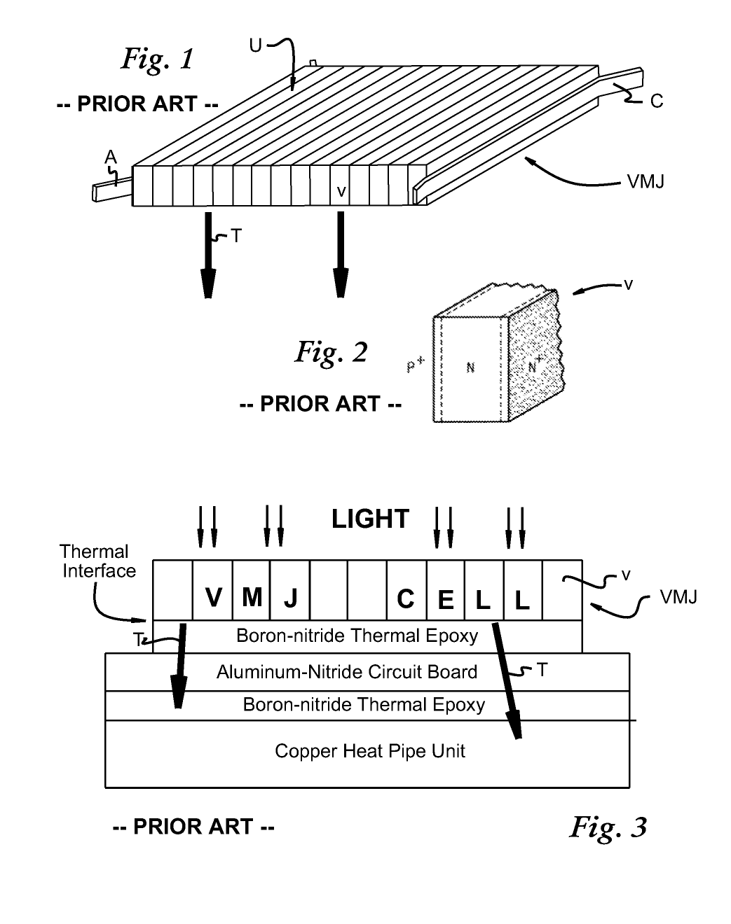

Now referring to FIG. 1, an oblique surface schematic view of a prior art edge-illuminated vertical multijunction photovoltaic receiver array is shown. As discussed in the above cited references incorporated herein in their entirety, vertical multijunction photovoltaic receiver VMJ as shown comprises a series of ganged or fused together individual cells v that are disposed to allow that an entry side U can exposed to an incoming beam, such as concentrated sunlight, a laser beam or other energy-containing flux as defined under the term, beam, in the Definitions section. FIG. 2 shows an oblique surface schematic view of a individual cell from the prior art vertical multijunction photovoltaic receiver array illustratively shown in FIG. 1. As marked, P+, N, and N+—collectively known in industry as P+NN+, refers to heavy extrinsic doping, such that in silicon, for example, the n+ and p+ designations refer to doping that is sufficient to cause bulk resistivity in the range of milliOhm-cm. This is in contrast to resistivity in the range of Ohm-cm for intrinsic semiconductors.

The optoelectronic feed to vertical multijunction photovoltaic receiver VMJ of FIG. 1 is a dual, cross-device feed comprising an anode A and a cathode C as shown. As photovoltaic energy conversion under high intensity light occurs, a relatively large schematically shown thermal flow T flows out of the device, shown downward on the page.

This substantial attempted thermal loading is addressed in prior art structures in a way that is typified by the prior art edge-illuminated vertical multijunction photovoltaic receiver array shown as a cross-sectional schematic diagram in FIG. 3, where prior art thermal mounting and schematic thermal flow T are shown. As can be seen, thermal flow T travels essentially in one overall direction, across the base of the vertical multijunction cell shown in the figure, where in order of passage, the thermal flow T traverses and conducts through known layers, shown illustratively as a boron-nitride thermal epoxy, followed by an aluminum-nitride circuit board, which in turn is supported by another layer of boron-nitride thermal epoxy in turn in direct thermal contact with a plurality of copper heat pipe units or the equivalent. These thermal management material selections are known by those skilled in the semiconductor device arts and have limitations that do not allow successful deployment of many three-dimensional or relatively flat optoelectronic device billets and energy conversion devices served by the instant invention.

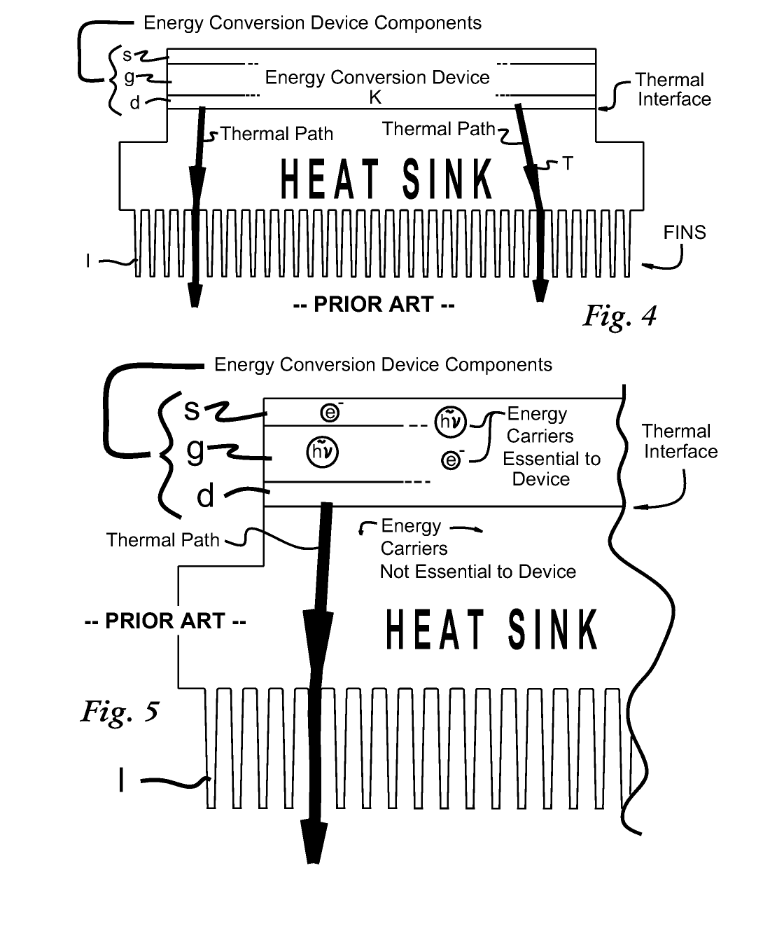

Referring now to FIG. 4, a cross-sectional schematic diagram of a general energy conversion device similar to the illustrative vertical multijunction photovoltaic receiver of FIG. 3 is shown, with schematic illustrative thermal flow. An energy conversion device (shown, Energy Conversion Device) comprising three Energy Conversion Device Components s, g, and d (such as the source, gate and drain of a MOSFET) is shown schematically. The energy conversion device, outside of desired thermal dissipation requirements, is self-sufficient and unitary in overall construction. The energy conversion device is bonded thermally to a known heat sink (shown, HEAT SINK) at a Thermal Interface using known means.

The thermal interface can include thermal grease, gel, or heat sink compound, as known by those skilled in the art. Thermal grease is typically electrically insulating, but thermally conductive, helping to eliminate air pockets, and can comprise various polymerizable liquid matrix compounds and liberal amounts of electrically insulating, but thermally conductive filler compounds. In common use by those skilled in the art are epoxies, silicones, urethanes, and acrylates, which are used to suspend finely divided or particulate aluminum oxide, boron nitride, zinc oxide, and aluminum nitride. A thermal interface can include known anti-reflective coatings, or other materials like mica that can serve other simultaneous design objectives.

The prior art heat sink comprises FINS of known construction and design to increase surface area and to lower thermal resistance by increasing thermal dissipation by known natural convection and radiative processes. Shown on the diagram is a Thermal Path, using heavy black lines and arrows, giving an illustrative simplified depiction of the negative gradient of temperature which traverses the thermal interface, passes downward on the page through the heat sink, and passes out to the ends of each individual fin I shown in the arrays of fins (FINS) depicted.

Now referring to FIG. 5, a close-up view of the cross-sectional schematic diagram of the general energy conversion device of FIG. 4 is shown. When energized, the energy conversion device by definition comprises energy carriers that are essential to operation of the device (shown abbreviated, Energy Carriers Essential to Device with circled iconic depiction symbols e- and hv) and these energy carriers are confined (as shown) to the energy conversion device. The term, energy carriers as well as the phrases like, Function of an energy conversion device are defined in the Definitions section for specific meaning in the instant specification and appended claims.

Now referring to FIG. 6, a top partial surface view, looking down, is shown of a relatively flat general energy conversion device like that shown in FIGS. 4 and 5, but embodying the instant invention. In the instant invention, an energy conversion device (K) is so constructed and formed to be in thermal communication with a plurality of fins I (FINS) which at least partially form a heat sink, and each of the fins
[1] originates from inside the energy conversion device and emerges across a local device boundary (Device boundary);
[2] is formed in a thermally unitary manner from an energy conversion device component, such as a lamination of a vertical multijunction photovoltaic array or a source, gate, drain of a MOSFET, or an emitter, collector or base of an array of bipolar junction transistors; and this energy conversion device component inherently
[3] individually supports traffic in energy carriers essential to the function of the energy conversion device.

In the thermal path illustratively shown, heat is illustratively drawn from neighboring energy conversion device components, and passes out of the device without requiring a thermal interface.

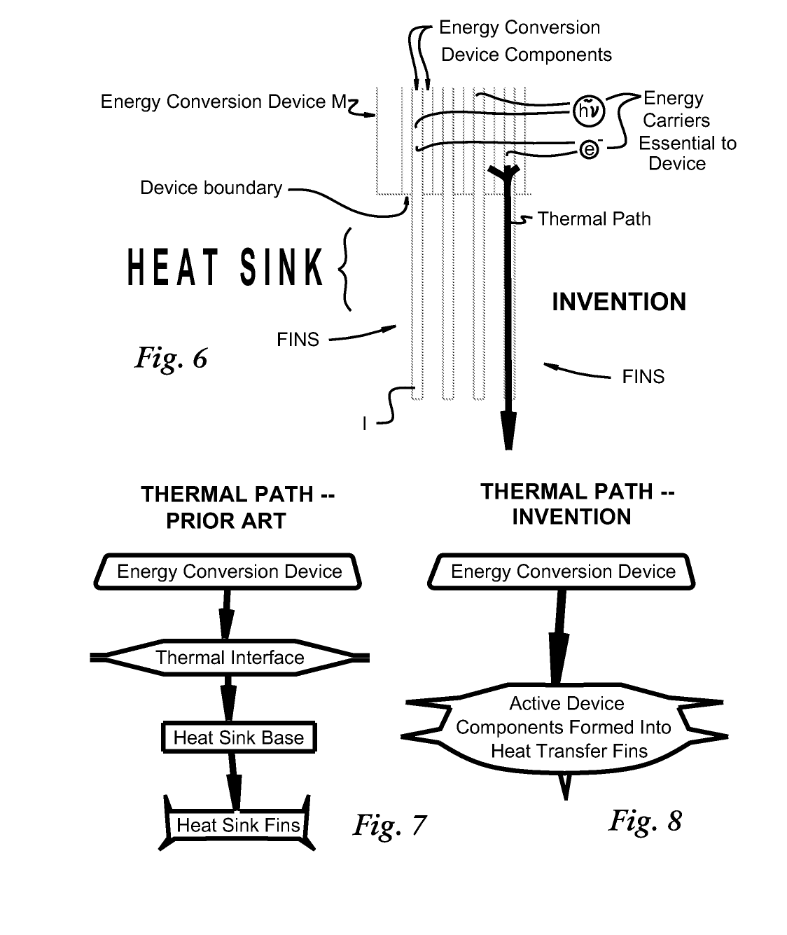

This is shown by reference to FIGS. 7 and 8. FIG. 7 shows a simplified schematic thermal flow chart for a prior art general energy conversion device using a conventional prior art heat sink, with an illustrative thermal path again shown using heavy black lines. Heat passes from the Energy Conversion Device across a Thermal Interface to a Heat Sink Base located exterior of the energy conversion device. From the heat sink base, heat can optionally pass out through an array of Heat Sink Fins.

There is increased thermal resistance at the thermal interface where a prior art heat sink is thermally and mechanically bonded to a heat sink base. This results in a decrease of thermal throughput in watts for a given device and device geometry. The thermal path crosses a thermal and mechanical plane formed by the heat sink surface.

This is in contrast to the scheme of the instant invention. FIG. 8 shows a simplified schematic thermal flow chart for cooling of a general energy conversion device, where the thermal path is direct, emerging from Active Device Components Formed Into Heat Transfer Fins as indicated above and in the description for FIG. 6. No heat sink base plane is required and no thermal interface, thermal grease, etc., is required.

Applications can be found for energy conversion devices that handle large amounts of input or output energy, such as vertical multijunction photovoltaic cell arrays and semiconductor lasers for power receiving and beaming.

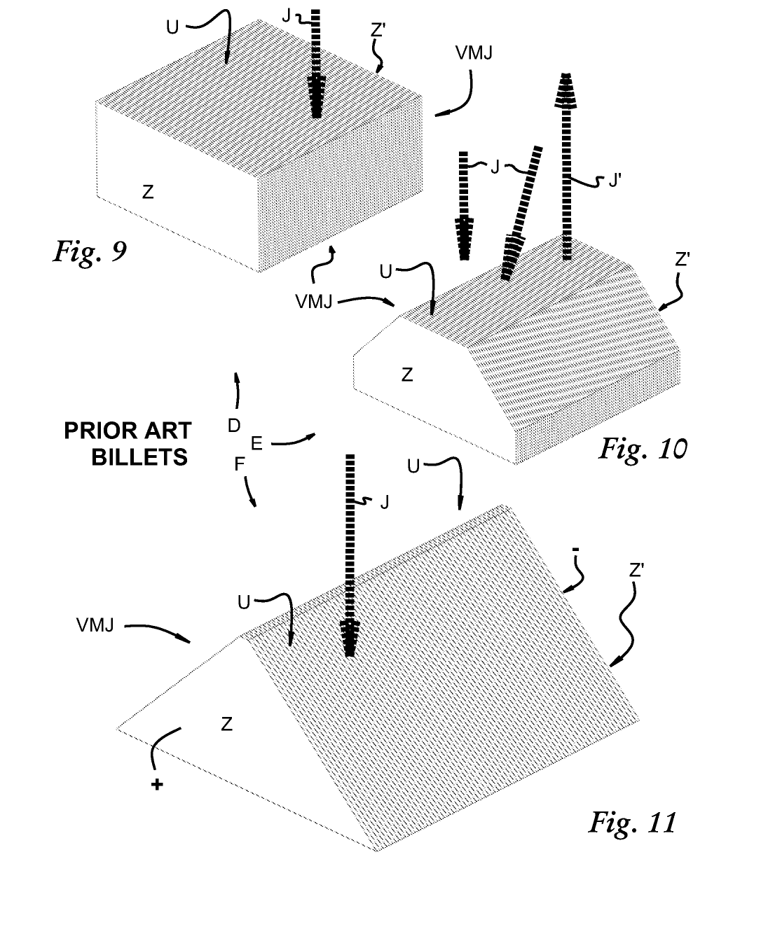

FIGS. 9-11 show oblique surface views of three illustrative prior art three-dimensional energy conversion or optoelectronic device billets that can be improved by practicing the invention, with incident beams impinging upon or emerging from billet entry sides. Incident beams J are illustratively shown impinging upon billet entry sides U. These billets shown are defined more generally in the Definitions section and are merely illustrative and also serve to represent with clarity and simplicity the emphasis in this disclosure upon photovoltaic receivers and vertical multijunction photovoltaic receivers, but shall not limit the scope of the appended claims. As can be seen, FIG. 9 shows a rectangular billet made from a plurality of planar individual wafers or cells, while FIG. 10 shows a similar stack made from trapezoidal shapes pieces, and while FIG. 6 shows a billet in the shape of a triangular prism. The shapes of the optoelectronic or vertical multijunction photovoltaic receiver billets can meet fabrication objectives and/or can enhance edge-illumination light entry. This can allow maximizing light gathering properties based on the design of wave guide receivers, as described below. Each of the three-dimensional optoelectronic device billet D and/or three-dimensional photovoltaic receiver billet E can optionally comprise a first opposing billet surface Z and a second opposing billet surface Z′ which are at opposite ends of the stacks of wafers or cells, but the term, opposing surfaces, as defined in the Definitions section shall be controlling. In the three-dimensional photovoltaic receiver billet shown in FIG. 6, first opposing billet surface Z is shown as a surface which carries a positive charge (+), while second opposing billet surface Z′ is shown carrying a negative charge (−), which result from the photovoltaic process across series-connected individual photovoltaic cells. Three-dimensional photovoltaic receiver billet E is also illustratively shown with an alternative possibility—an outgoing beam J′ is shown emerging from exit surface U′ of three-dimensional photovoltaic receiver billet E. As indicated in the parent US patent application to this disclosure, an output beam, such as a communications beam, possibly originating from a three-dimensional optoelectronic device billet otherwise receiving beam energy, can be produced, such as for communication purposes with an entity possibly engaged in energy transfer. Such an output energy conversion device billet can comprise known output devices such as any light-emitting diode, a solid state diode laser, a three-dimensional laser, a vertical-external-cavity surface-emitting-laser, or a vertical cavity surface-emitting laser, or future devices not yet contemplated.

Fabrication and operation of vertical multijunction photovoltaic receivers is known in the art. For example, 40 diffused p+nn+ silicon wafers of 250 microns thickness can be metallized, stacked and alloyed together to form a multi-layer stack that is 1 cm high. This stack of diffused wafers, when appropriately cut, will yield around 1000 VMJ cells of 1 cm×1 cm×0.05 cm size, each containing 40 series connected unit cells for high voltage operation. Exposed silicon surfaces are etched in a known manner to remove saw damage and passivated with a known anti-reflection coating applied to the illuminated side.

In this way, a 2 cm×2 cm vertical multijunction photovoltaic receiver can be fabricated that generates 80-100 volts under intense light. This can generate 200 watts at 2 amps. In a conventional photovoltaic cell, that same power might require upwards of 180 amps, which can be very problematic for power management.

Only simple billets are shown for clarity. Those skilled in the art of fabrication of optoelectronic or energy conversion devices or energy conversion device billets can supplement the structures shown with associated components, including side reflectors, lenses or other refractive elements, sensors, and collimators and the like, without departing from scope of the invention as expressed in the appended claims.

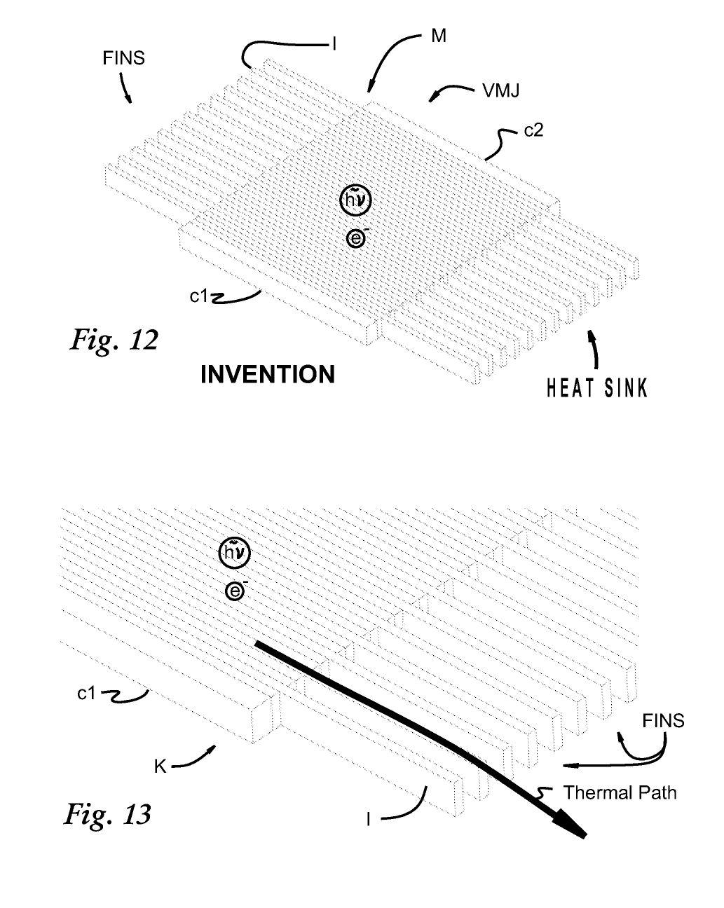

A surface view of a possible embodiment of the instant invention is shown in FIGS. 12 and 13. FIG. 12 shows an oblique surface view of an energy conversion device illustratively shown with an energy conversion device M given as a relatively flat vertical multijunction photovoltaic cell array with heat sinking provided in the manner described above. Output (anode, cathode) contacts c1 and c2 are provided as shown.

Each individual fin I in the fin array (FINS) of the heat sink emerges as an internal entity from within the device M, individually supporting traffic in energy carriers essential to the function of the energy conversion device.

FIG. 13 shows a close-up of a portion of the oblique surface view of the energy conversion device of FIG. 12, showing a thermal path for heat dissipation, running along the length of a energy conversion device component, passing directly out of the device to outside environment.

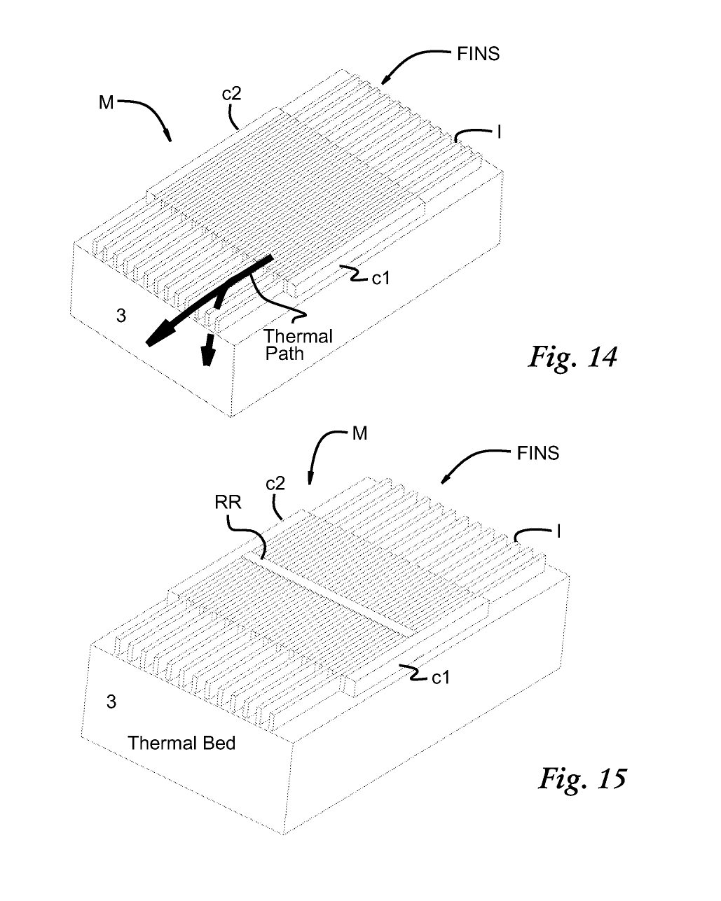

Now referring to FIGS. 14 and 15, oblique surface views of another embodiment of an energy conversion device are illustratively shown as a relatively flat vertical multijunction photovoltaic cell array with heat sinking provided according to the instant invention, featuring a thermal bed 3 that is in direct thermal communication with the array of fins (FINS). The thermal path is therefore enhanced, utilizing convection, and conduction to the thermal bed, whose construction from aluminum, copper, or other thermal conductors is known to those skilled in the art. FIG. 15 shows a similar device embodiment of the invention, additionally comprising a retroreflector RR affixed across the energy conversion device M, which can be used for location purposes in power beaming applications.

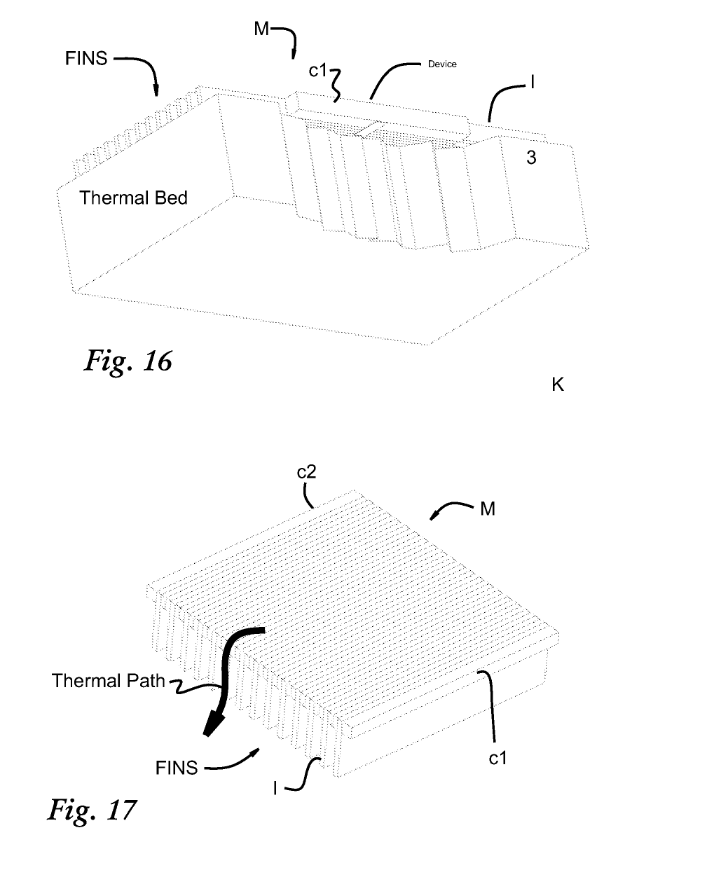

The retroreflector RR can be located inside or underneath the device as shown in FIG. 16, which shows an underside oblique surface view of the energy conversion device of FIG. 15, with the retroreflector tucked underneath. This protects the retroreflector and with many semiconductors such as silicon transparent to various electromagnetic wavelengths, the retroreflection still occurs.

FIG. 17 shows an oblique surface view of an energy conversion device similar to that illustratively shown previously as a relatively flat vertical multijunction photovoltaic cell array with heat sinking provided according to the instant invention of FIG. 12, with energy conversion device components forming a heat sink array under the device. The thermal path, as illustratively shown, passes downward on the page. This alternative form factor can be combined with the side-emerging fins as previously shown.

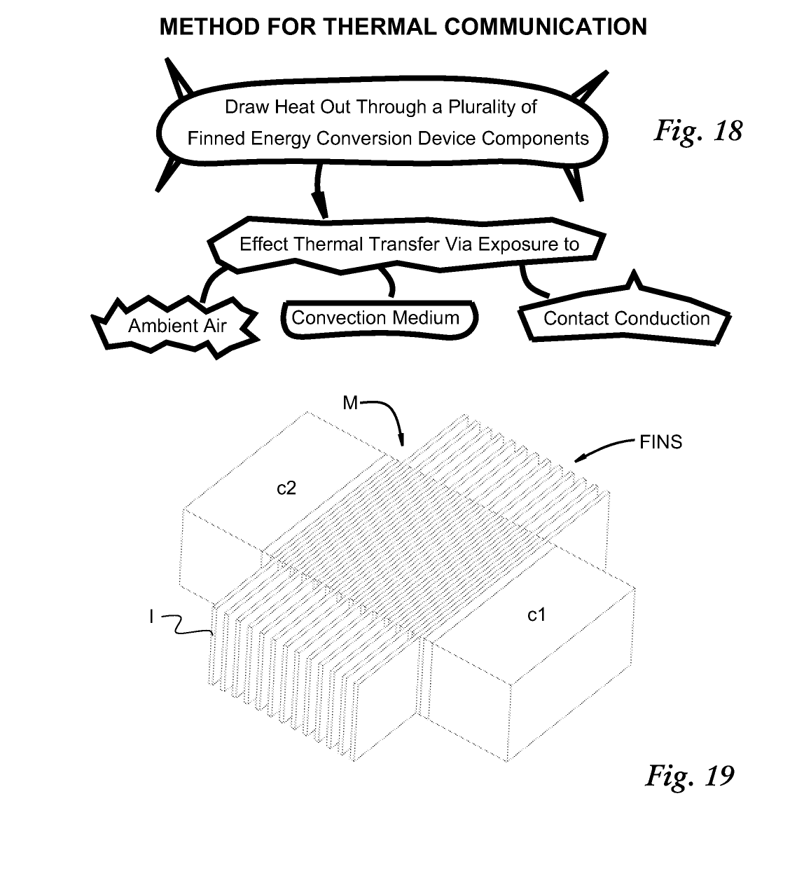

Once a fin according to the invention emerges from an energy conversion device, thermal dissipation can be facilitated further. FIG. 18 shows simplified schematic chart for a method for thermal communication according to the invention, comprising the following steps:
[1] Draw Heat Out Through a Plurality of Finned Energy Conversion Device Components, then
[2] Effect Thermal Transfer Via Exposure to Ambient Air, and/or a Convection Medium and/or via Contact Conduction as those skilled in the device fabrication arts can appreciate.

As an alternative embodiment, FIG. 19 shows an oblique surface view of an energy conversion device according to the invention with a heat sink array and additional heat sink holding structures labeled c1 and c2, which can double as device contacts, such an optical or electrical contacts.

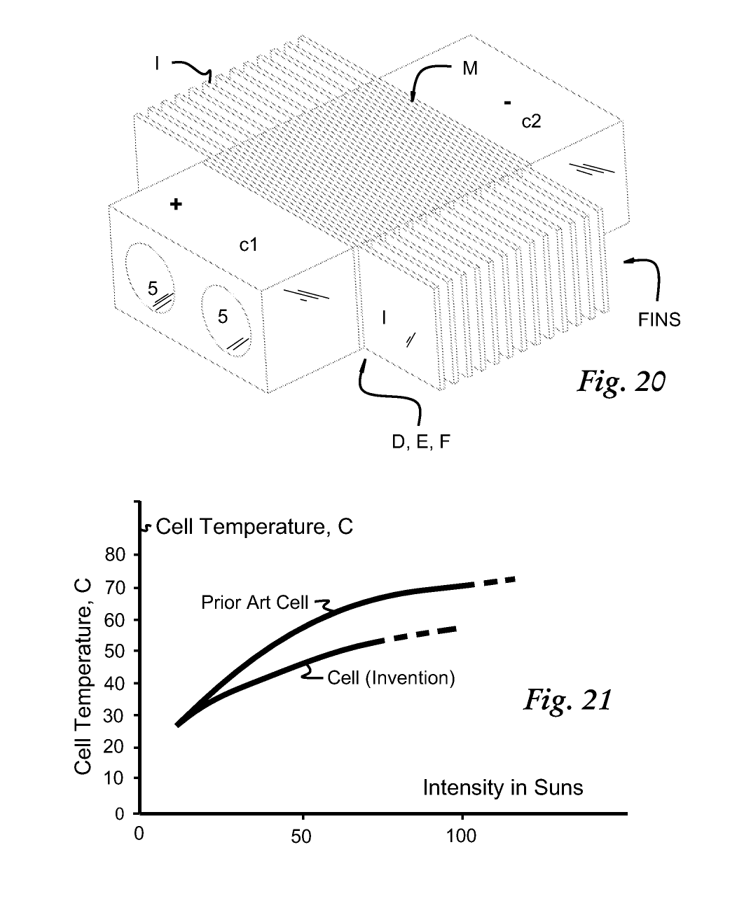

FIG. 20 shows an oblique partial cut-out surface view of an energy conversion device illustratively shown as a three-dimensional energy conversion or optoelectronic device billet according to the invention similar to that shown in FIG. 19, and showing illustrative internal and external cooling systems inside the heat sink holding structure. The entire energy conversion device M can be drilled or fabricated to comprise a passage or series of passages 5 for circulation of cooling fluid such as water or oil.

The teachings of the instant invention can be used to great advantage to obtain lower device operating temperatures, such as for semiconductor device billets, like vertical multijunction photovoltaic arrays exposed to concentrated solar light. FIG. 21 shows a simple representative cartesian plot of the cell operating temperature of an energy conversion device vertical multijunction cell array as a function of incident intensity of light for photovoltaic conversion, for both a prior art device and a device using the instant invention. As can be seen from the plot, photovoltaic receiver cell arrays using the heat sinking as taught by the instant invention operate at lower temperatures for a given light incidence power level. A standard experimental control cell using prior art techniques reached 52 C under 45 suns, while a similar cell array using the invention was able to convert 68 suns and remain at 51.9 C. This ability to handle increased input power can itself make possible devices that would otherwise not survive thermal stresses. A typical drone input beam application, for example, might require 70 watts input power beamed into it via a laser, and it is power handling considerations like this that can be determinative for the success of new applications.

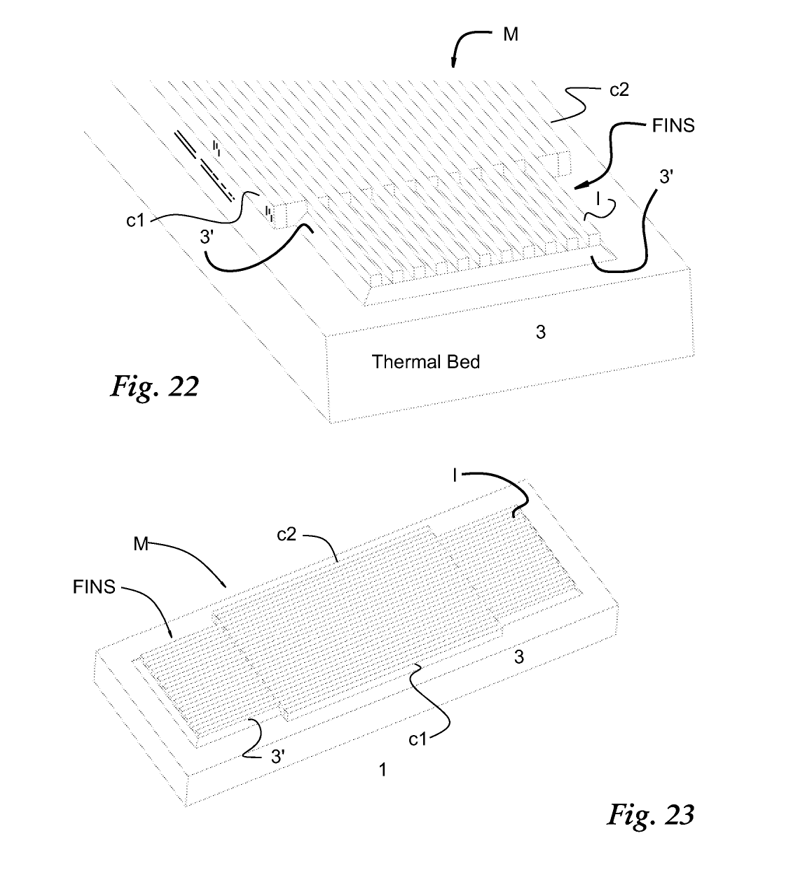

Alternative embodiments of the invention can include customized thermal beds. FIGS. 22 and 23 show differing oblique surface views of a relatively flat energy conversion device with heat sinking according to the invention, using twin thermal beds. A main thermal bed 3 can be a large block, such as made from copper, while a “liner” smaller bed 3′ can be made from indium metal, with an insulator coating, such as an electrically insulative antireflective coating protecting the energy conversion device from shorting, as those skilled in the art can appreciate. The addition of an indium thermal bed using techniques known in the device fabrication arts can enhance the thermal throughput of each individual fin I as provided according to the invention. The thermal conductivity of indium does not appreciably change as a function of temperature.

The thermal beds 3 can be made from a variety of known materials such as aluminum nitride or boron nitride in bulk. The energy conversion devices of the instant invention can be mounted on aluminum nitride board, and mounting can include commercially available thermally conductive pads such as T-preg™ manufactured by Laird PLC (Delaware, USA). Whether one uses ambient air to cool the fins of the instant invention, or an indium contact medium can depend on application design constraints. For a drone power-beaming application, air can suffice. For a cell phone charging application where the instant invention is used to convert laser energy to electricity, an indium bed can be integrated into the system architecture.

In experiments conducted, no cooling fans were used to ventilate any heat sinks. A 50-lamination 10×10 mm top area conventional Si based vertical multijunction photovoltaic device was affixed to an aluminum nitride thermal bed, and locally affixed using a T-preg™ thermal pad. This device was compared with one according to the invention, where the same 10×10 mm device obtained the benefit of two areas of 10×12 mm finned areas like that shown in FIG. 14. Ambient air was 30 C, and a light source used for stimulation was a 35 watt 915 nm wavelength laser. Temperatures were measured with a thermocouple by taking temperature readings from back side of the AlN substrate thermal bed.

In the optoelectronic feeds as shown, it is not strictly necessary to have an electrical feed, as an alternative optical feed can be used, such as for optical transducers, optical devices and the like. A ruby crystal conveying high intensity light can be used as a billet and the light can be conveyed via an optoelectronic feed as taught herein, and used or converted using structures or components not explicitly shown.

The heat sink holding structure of the invention can be fabricated from solid copper, such as a 5×5×5 cm block. The invention as described can be used to allow optical refueling of electric platforms such as MUAVs airships, robotic exploration vehicles and other remote vessels.

Waveguide surfaces and energy conversion device surfaces can be treated to form surface coatings that are designed to meet engineering objectives for various wavelengths of anticipated incident beams, including transparency, surface adhesion, high thermal conductivity and matched thermal expansion. The atomic layer deposition (ALD) process can be used to form such coatings, as is known in the surface treatment arts, and can comprise Al2O3, or AlN, which can act as a heat spreader. Other known oxides and alloys can be used. In this way, many components can be made from copper or other inexpensive materials, yet achieve specialized objectives.

In addition, wafers can include advanced SiC (silicon carbide) wafers, such as made by Dow Corning, Midland, Mich., USA. As conventional silicon approaches physical limits, materials sourcing has evolved and high-crystal quality silicone carbide (SiC) wafers can offer advantageous properties, resulting in wider electronic band gaps, high overall efficiencies, and higher thermal conductivity. This is attractive to many industries, including manufacturers of diodes and photovoltaic receivers and cells.

What results from applying the teachings of the invention is a new allowed operating regime for energy conversion devices, including for vertical multijunction photovoltaic cell arrays that allows for new application that were not heretofore possible.

As those skilled in the art can contemplate, any beam or sunlight receivers used for energy conversion devices shown here can be orientable, transferable and shielded when necessary by a moving cover or canopy. Any known communication protocol can be used in conjunction with any incoming beam J or outgoing beam J′.

Those skilled in the engineering arts will appreciate that many possible schemes are permitted using the elements and teachings of the instant invention.

Other optical elements can be interposed between the elements of the appended claims without departing from the scope of the invention, as those skilled in the art can add desired functional steps or elements to serve needed ends in a particular application.

For example, components can be added, such as frequency discriminators such as a cold mirrors, etc. Curved or other focusing geometries can be employed in lieu of some of the planar surfaces illustratively depicted.

All of the elements as taught and claimed can be under an enclosure, lens, canopy, fluid or light-transmitting body without departing from the scope of the invention, as those skilled in the art may elect to protect, amplify, modify, or create in an alternative fashion energy conversion of high intensity light as taught in this disclosure.

There is obviously much freedom to exercise the elements or steps of the invention.

The description is given here to enable those of ordinary skill in the art to practice the invention. Many configurations are possible using the instant teachings, and the configurations and arrangements given here are only illustrative.

Those with ordinary skill in the art will, based on these teachings, be able to modify the invention as shown.

The invention as disclosed using the above examples may be practiced using only some of the optional features mentioned above. Also, nothing as taught and claimed here shall preclude addition of other reflective structures or optical elements.

Obviously, many modifications and variations of the present invention are possible in light of the above teaching. It is therefore to be understood that, within the scope of the appended claims using the Definitions given above, the invention may be practiced otherwise than as specifically described or suggested here.

We claim:

1. An energy conversion device (M) in thermal communication with a plurality of fins at least partially forming a heat sink, each of said fins
[1] originating from inside said energy conversion device;
[2] formed from an energy conversion device component; and
[3] individually supporting traffic in energy carriers essential to the function of said energy conversion device.

2. The energy conversion device of claim 1, wherein said energy conversion device is a vertical multijunction (VMJ) cell array.

3. A method for thermal communication with energy conversion device components in an energy conversion device (M), said method comprising:
[1] drawing heat out through a plurality of said energy conversion device components that individually support traffic in energy carriers essential to the function of said energy conversion device, where said plurality of energy conversion device components are finned and protrude sufficiently beyond a device boundary to allow significant thermal transfer;
[2] effecting said significant thermal transfer from said finned energy conversion device components via exposure to at least one of ambient air, a convection medium, and contact conduction with a thermal bed (3. 3′).

4. The method for thermal communication of claim 3, wherein said energy conversion device is a vertical multijunction (VMJ) cell array.

5. A heat sink array for an energy conversion device (M), said heat sink array comprising:
a plurality of fins, each of said fins originating from inside said energy conversion device, formed from an energy conversion device component; and individually supporting traffic in energy carriers essential to the function of said energy conversion device.

6. The heat sink array for an energy conversion device of claim 5, wherein said energy conversion device is a vertical multijunction (VMJ) cell array.

7. The heat sink array for an energy conversion device of claim 5, wherein at least some of said fins are so formed and positioned to be in direct thermal communication with a thermal bed (3, 3′) via contact conduction.
